(19) United States
(12) Patent Application Publication
(10) Pub. No.: US 2016/0283321 A1
(43) Pub. Date: Sep. 29, 2016

(54) Systems and Methods for Flash Memory Access

(71) Applicant: Avago Technologies General IP (Singapore) Pte. Ltd., Singapore (SG)

(72) Inventors: Shaohua Yang, San Jose, CA (US); Xuebin Wu, San Jose, CA (US); Yang Han, Sunnyvale, CA (US)

(21) Appl. No.: 14/672,115

(22) Filed: Mar. 28, 2015

(51) Int. Cl. G06F 11/10; H03M 13/11; G11C 29/52

(52) U.S. Cl. CPC G06F 11/1068; G11C 29/52; H03M 13/1148; H03M 13/1108; H03M 13/1128

(57) ABSTRACT

Embodiments are related to systems and methods for data processing, and more particularly to systems and methods for processing data accessed from a flash memory.

### FIELD OF THE INVENTION

Embodiments are related to systems and methods for data processing, and more particularly to systems and methods for processing data accessed from a flash memory.

### BACKGROUND

Various data storage systems have been developed that include flash memory devices. Access to such flash memory devices is done with reasonably low latency where no errors occur. When errors occur, however, processing approaches used to correct the errors may be time consuming. As an example, processes have been developed to generate soft data from the information read from the flash memory device, and then to correct errors using that soft data. Such an approach takes considerable time.

Hence, for at least the aforementioned reasons, there exists a need in the art for advanced systems and methods for accessing data from a flash memory.

### SUMMARY

Embodiments are related to systems and methods for data processing, and more particularly to systems and methods for processing data accessed from a flash memory.

Some embodiments of the present invention provide a system for accessing a flash memory device. The system includes a flash memory read circuit including: a hard data processing circuit, an accumulated syndrome circuit, and a multi-codeword parity based processing circuit. The hard data processing circuit is operable to apply a hard data decoding algorithm to a set of hard data derived from flash memory cells, where application of the hard data decoding results in converged codewords and at least one non-converged codeword. The accumulated syndrome circuit operable to compute a partial syndrome of the converged codewords. The multi-codeword parity based processing circuit includes: a cross codeword error correction circuit operable to calculate a soft data adjustment value based at least in part upon the at least one non-converged codeword; and a data decoding circuit operable to apply a secondary data decoding algorithm to the at least one non-converged codeword guided by a decoder input generated in part from the soft data adjustment value.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment or one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a solid state storage device including a hard data processing circuit, a multi-codeword parity based processing circuit, and an iterative data processing circuit in accordance with some embodiments of the present invention;

FIGS. 2a-2c show one implementation of a multi-codeword parity based encoding circuit in accordance with one or more embodiments of the present invention;

FIG. 3 depicts one implementation of an iterative data processing circuit that may be used in relation to embodiments of the present invention;

FIG. 4 shows a data processing circuit applying a multi-codeword parity based processing in accordance with some embodiments of the present inventions; and

FIGS. 5a-5c are flow diagrams showing a method for processing data accessed from a flash memory in accordance with various embodiments of the present invention.

### DETAILED DESCRIPTION OF SOME EMBODIMENTS

Embodiments are related to systems and methods for data processing, and more particularly to systems and methods for processing data accessed from a flash memory.

Some embodiments of the present invention provide a system for accessing a flash memory device. The system includes a flash memory read circuit including: a hard data processing circuit, an accumulated syndrome circuit, and a multi-codeword parity based processing circuit. The hard data processing circuit is operable to apply a hard data decoding algorithm to a set of hard data derived from flash memory cells, where application of the hard data decoding results in converged codewords and at least one non-converged codeword. The accumulated syndrome circuit operable to compute a partial syndrome of the converged codewords. The multi-codeword parity based processing circuit includes: a cross codeword error correction circuit operable to calculate a soft data adjustment value based at least in part upon the at least one non-converged codeword; and a data decoding circuit operable to apply a secondary data decoding algorithm to the at least one non-converged codeword guided by a decoder input generated in part from the soft data adjustment value.

In some instances of the aforementioned embodiments, the partial syndrome is computed by XORing the bits in bit positions that are protected by the cross codewords error correction codeword of the converged codewords. It should be noted in other cases where no converged codewords occur, the accumulated syndrome would be all zeros. In various instances of the aforementioned embodiments, the secondary data decoding algorithm is a low density parity check decoding algorithm. In one or more instances of the aforementioned embodiments, the at least one non-converged codeword includes at least a first non-converged codeword and a second non-converged codeword. In such instances, applying the secondary data decoding algorithm yields a first converged codeword corresponding to the first non-converged codeword, and a third non-converged codeword corresponding to the second non-converged codeword. In some such instances, the flash memory read circuit further includes an iterative data processing circuit operable to: receive soft data corresponding to the third non-converged codeword, where the soft data is generated using multiple instances of the hard data of the third non-converged codeword each corresponding to different threshold values; and apply a tertiary data decoding algorithm to the third non-converged codeword guided by the soft data. In one particular case, the tertiary data decoding algorithm is a low density parity check decoding algorithm.

In some instances of the aforementioned embodiments, the system is implemented as part of a solid state storage device. In some such instances, the solid state storage device includes a flash memory device having the flash memory cells. In various instances of the aforementioned embodiments, the system is implemented as part of an integrated circuit.

Other embodiments of the present invention provide methods for accessing a flash memory device. The methods include: providing a flash memory device that includes a data block including at least: a first codeword, a second codeword, a third codeword, and a cross codewords error correction codeword; accessing the data block from the flash memory device; applying a hard data decoding algorithm to the data block where application of the hard data decoding results in a converged codeword corresponding to the first codeword, a first non-converged codeword corresponding to the second codeword, a second non-converged codeword corresponding to the third codeword, and a decoded version of the cross codewords error correction codeword; computing a partial syndrome of at least the converged codeword; using a multi-codeword parity based processing circuit to calculate a soft data adjustment value based at least in part upon a decoded output corresponding to the first non-converged codeword and the second non-converged codeword, and applying a secondary data decoding algorithm to the first non-converged codeword and the second non-converged codeword guided by a decoder input generated in part from the soft data adjustment value. Of note, if decoding of the cross codewords error correction codeword converges, then the syndrome is updated. Otherwise if decoding of the cross codewords error correction codeword fails, then the hard input or decoder output is buffered and used for calculation of the soft data adjustment value.

In some instances of the aforementioned embodiments, computing the partial syndrome of at least the converged codeword includes XORing the bits in bit positions that are protected by the cross codewords error correction codeword of the at least the converged codeword. In various instances of the aforementioned embodiments, the secondary data decoding algorithm is a low density parity check decoding algorithm. In one or more instances of the aforementioned embodiments, the converged codeword is a first converged codeword, and applying the secondary data decoding algorithm yields a second converged codeword corresponding to the first non-converged codeword, and a third non-converged codeword corresponding to the second non-converged codeword. In some such instances, the method further includes: receiving soft data corresponding to the third non-converged codeword, where the soft data is generated using multiple instances of the hard data of the third non-converged codeword each corresponding to different threshold values; and applying a tertiary data decoding algorithm to the third non-converged codeword guided by the soft data. In some cases, an entire data block is read from the flash memory and soft data is generated for the entire data block. In cases where only a portion of the soft data is needed in relation to failed codewords, the soft data related to other codewords may simply be discarded.

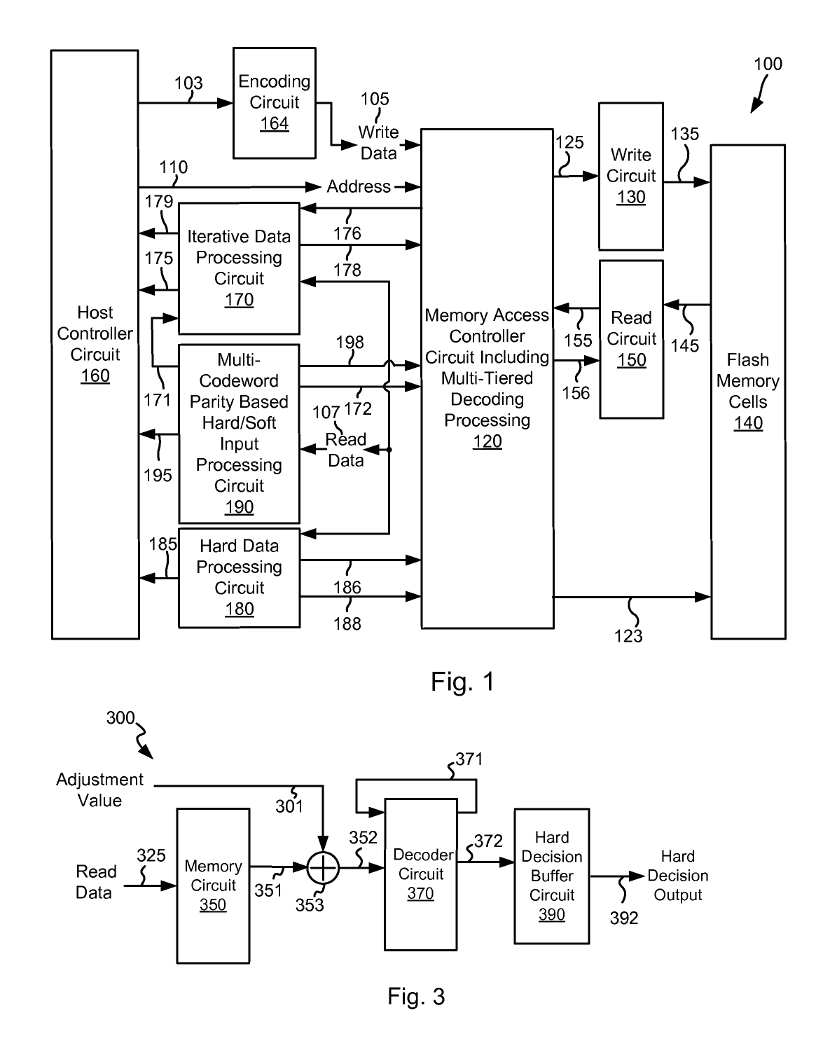

Turning to FIG. 1, a solid state storage device 100 is shown that includes a hard data processing circuit 180, a multi-codeword parity based hard/soft input processing circuit 190, and an iterative data processing circuit 170 in accordance with some embodiments of the present invention. Solid state storage device 100 includes a host controller circuit 160 that directs read and write access to flash memory cells 140. Flash memory cells 140 may be NAND flash memory cells or another type of solid state memory cells as are known in the art.

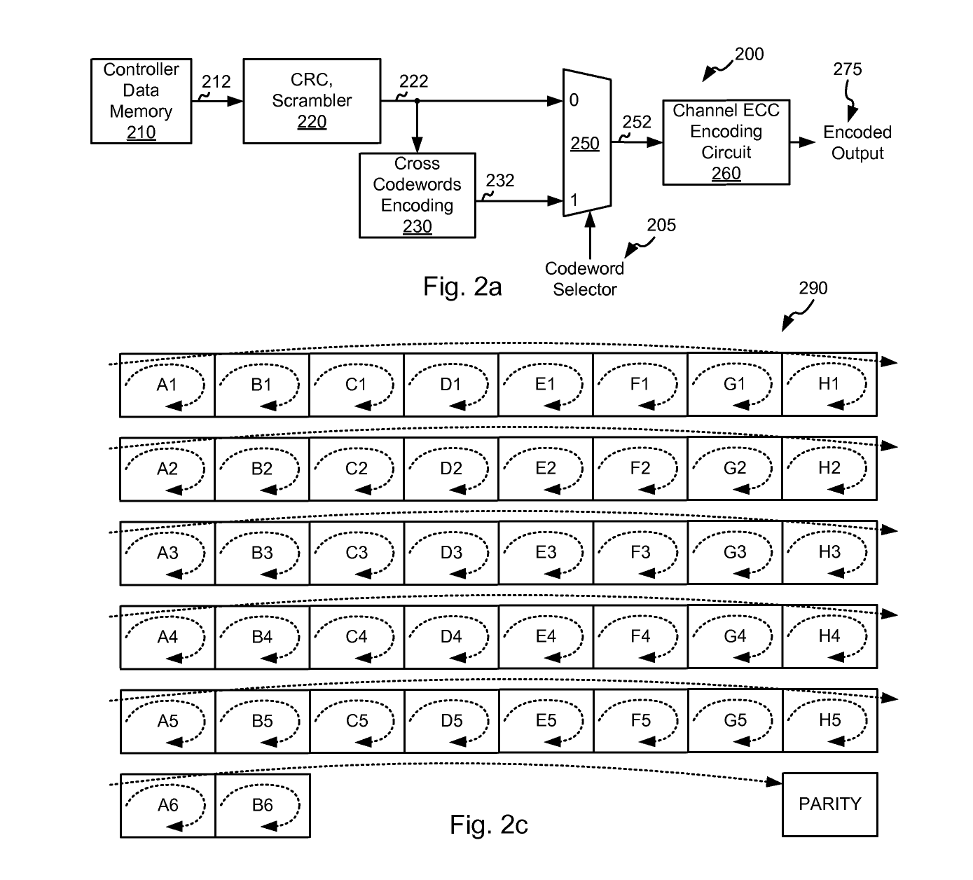

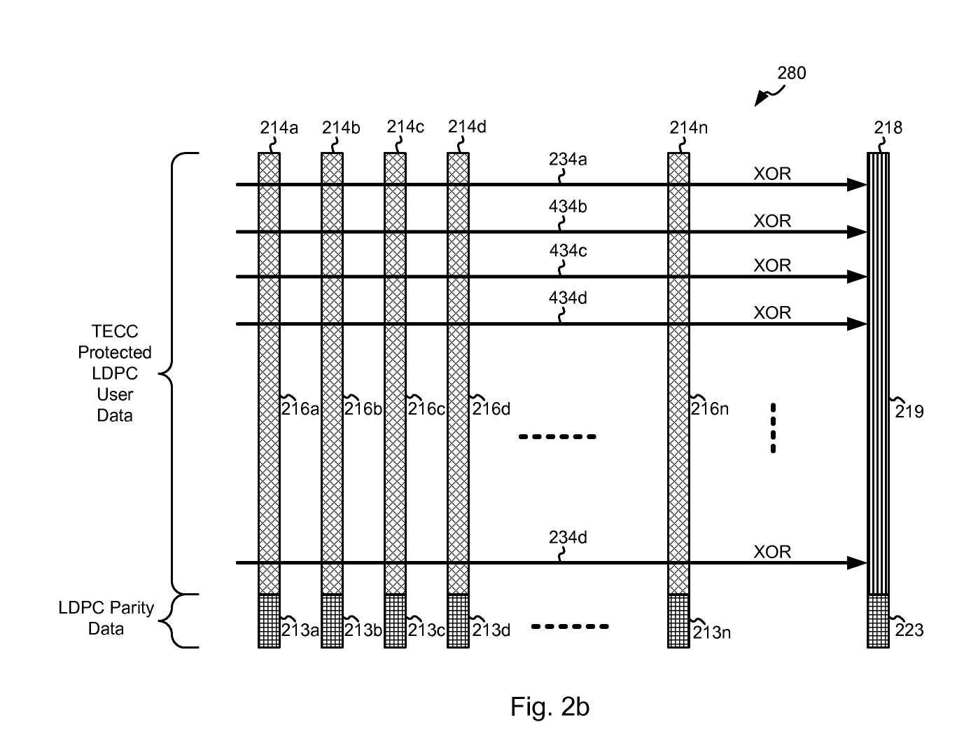

A data write is effectuated when host controller circuit 160 provides input data 103 to an encoding circuit 164 to yield a write data set 105. The encoding applied by encoding circuit 164 yields an encoded output corresponding to input data 103 and an additional cross codewords error correction codeword. Together, the encoded output and the additional cross codewords error correction codeword are provided as write data 105. In some cases, the encoded output is generated by encoding portions of input data 103 as low density parity check (LDPC) encoding as is known in the art, and the cross codewords error correction codeword is encoded by XORing corresponding portions of the LDPC codewords. One implementation of encoding circuit 164 is discussed below in relation to FIGS. 2a-2c.

A memory access controller 120 formats write data 105 and provides an address 123 and an encoded write data 125 to a write circuit 130. Write circuit 130 provides write voltage pulses 135 corresponding to respective groupings of encoded write data 125 that is used to charge respective flash memory cells addressed by address 123. For example, where flash memory cells are two bit cells (i.e., depending upon the read voltage, a value of ‘11’, ‘10’, ‘00’, or ‘01’ is returned), the following voltages may be applied to store the data:

| Two Bit Data Input | Voltage Output |
|---|---|
| ‘11’ | V3 |
| ‘10’ | V2 |
| ‘00’ | V1 |
| ‘01’ | V0 |

Where V3 is greater than V2, V2 is greater than V1, and V1 is greater than V0. Write circuit 130 applies a pulsed voltage to flash memory cells 140 according to encoded write data 125.

When a read back of previously stored data is desired, host controller 160 provides an address 110 to memory access controller 120 which is translated to a physical address and provided to flash memory cells 140 as address 123. In turn, flash memory cells 140 returns a block of data identified by address 123 as read voltages 145 that each represents individual bits or groups of bits in flash memory cells 140. Read circuit 150 compares read voltages 145 with read threshold values 156, and based upon the comparison hard data 155 is generated. Hard Data 155 is provided to memory access controller 120 where it is buffered. The phrases “hard data” or “hard decisions” are used in their broadest sense. In particular, “hard data” or “hard decisions” are outputs indicating an expected original input value (e.g., a binary ‘1’ or ‘0’, or a non-binary digital value). Based upon the disclosure provided herein, one of ordinary skill in the art will recognize a variety of hard decisions or hard data that may be used in relation to different embodiments of the present invention.

Memory access controller 120 causes application of up to three different processing algorithms to generate a data output to host controller circuit 160. In particular, memory access controller 120 transfers hard data 155 as read data 107 to hard data processing circuit 180. Hard data processing circuit 180 applies standard flash data processing. Each codeword within the accessed block of data that is corrected using the hard data algorithm applied by hard data processing circuit 180 is provided as a data output 185 to host controller circuit 160 and a syndrome for the converged codeword is provided as a syndrome output 186 to memory access controller circuit 120. Memory access controller circuit 120 accumulates the syndrome values of all converged codewords, and eliminates hard data 155 corresponding to the converged codewords from the buffer. In contrast, whenever a codeword within the accessed block of data that is not rendered error free using the hard data algorithm applied by hard data processing circuit 180, an error indicator 188 is provided to memory access controller circuit 120. Whenever memory access controller circuit 120 receives an indication of a failed codeword, hard data 155 corresponding to the codeword is maintained in the buffer for further processing.

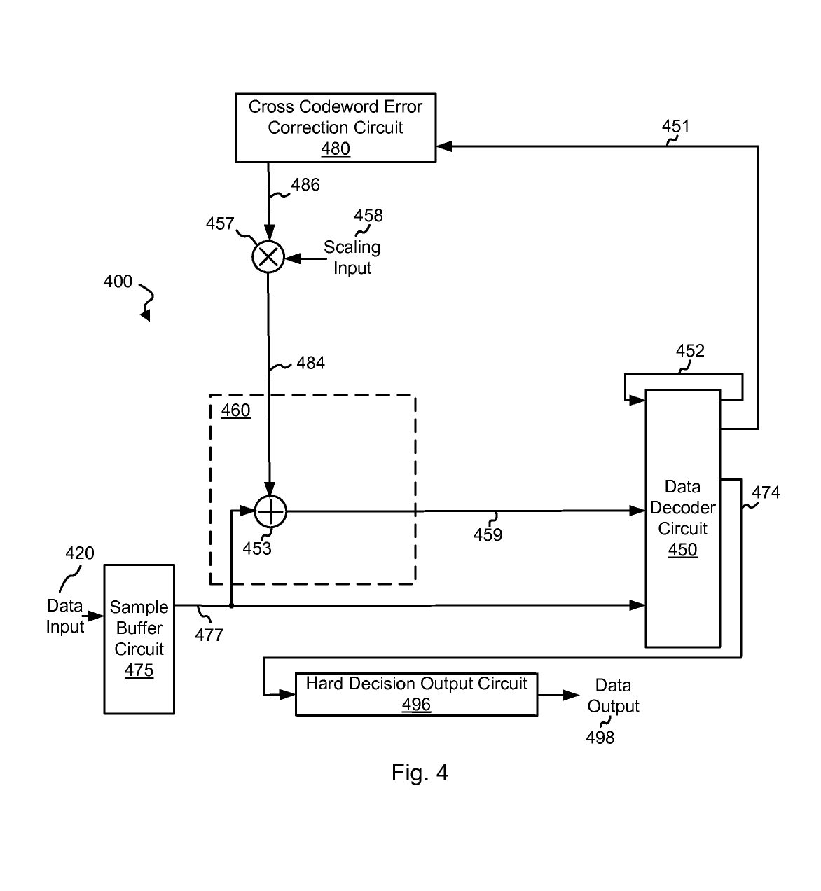

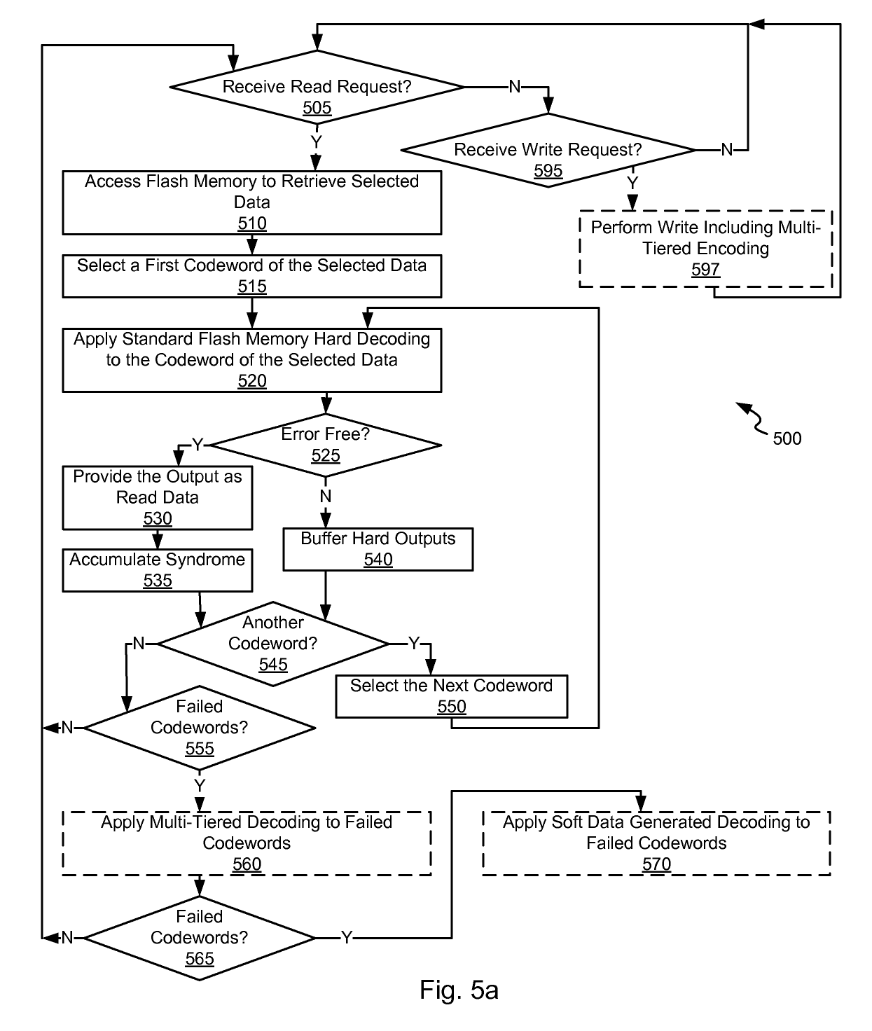

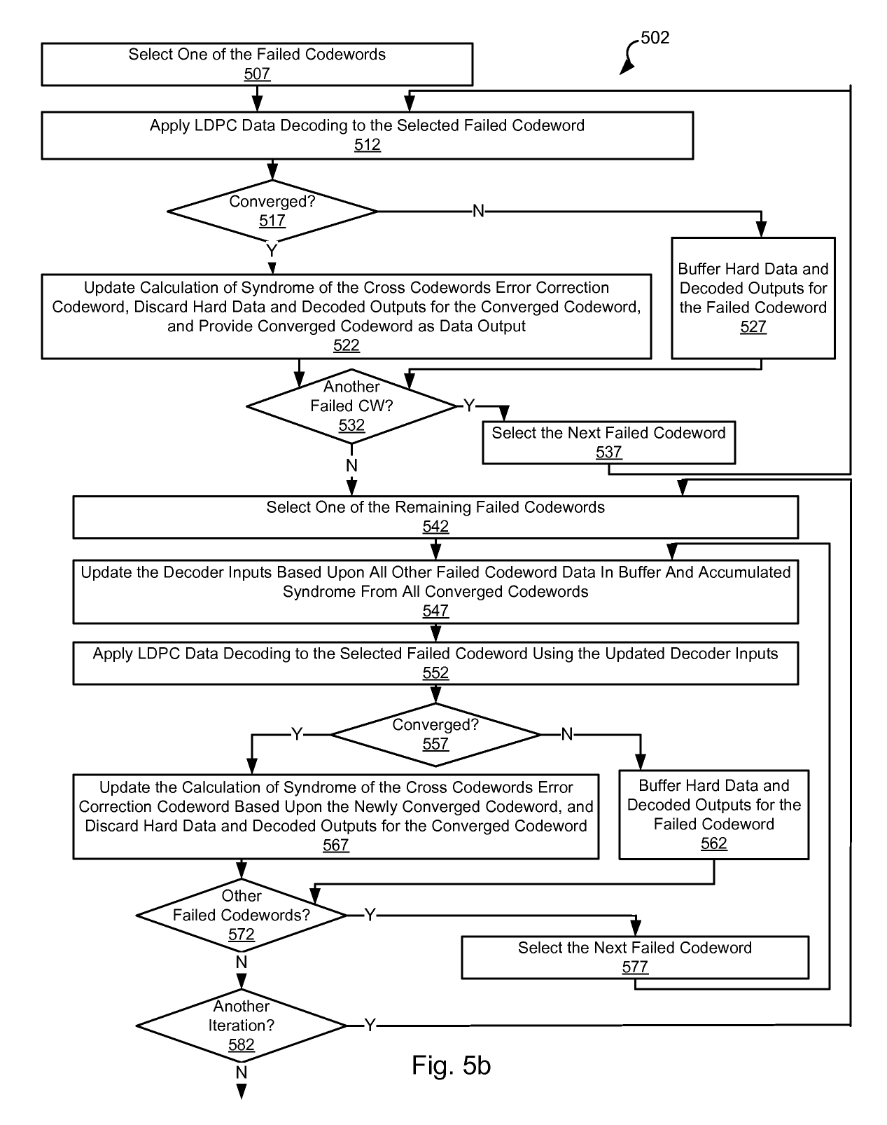

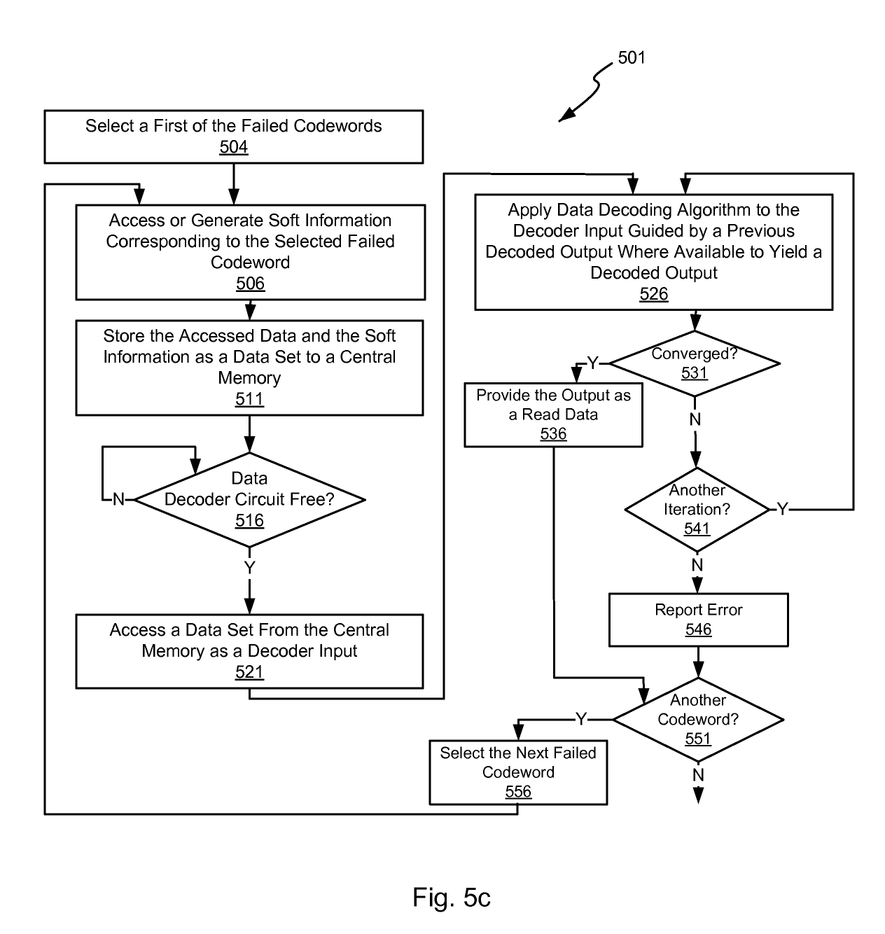

Once all codewords within the requested block have been processed by hard data processing circuit 180, memory access controller 120 transfers hard data 155 corresponding to the codewords that failed during processing by hard data processing circuit 180 to multi-codeword parity based hard/soft input processing circuit 190 as read data 107. In turn, to multi-codeword parity based hard/soft input processing circuit 190 processes the failed codewords using the cross codewords error correction codeword received as part of the retrieved block of data. During the processing, hard data corresponding to the failed codewords is received as read data 107 and decoded. The decoder circuit included as part of multi-codeword parity based hard/soft input processing circuit 190 accumulates syndrome and soft information based upon decoding using the cross codewords error correction codeword. This soft information is then used to guide additional iterations through the data decoder circuit. Each of the failed codewords that is corrected using the multi-codeword parity based hard/soft input processing circuit 190 is provided as a data output 195 to host controller circuit 160 and a syndrome for the converged codeword is provided as a syndrome output 172 to memory access controller circuit 120. Memory access controller circuit 120 accumulates the syndrome values of all converged codewords, and eliminates hard data 155 corresponding to the converged codewords from the buffer. In contrast, whenever a failed codeword is not rendered error free using the algorithm applied by multi-codeword parity based hard/soft input processing circuit 190, an error indicator 198 is provided to memory access controller circuit 120. Whenever memory access controller circuit 120 receives an indication of a failed codeword, hard data 155 corresponding to the codeword is maintained in the buffer for further processing. Multi-codeword parity based hard/soft input processing circuit 190 may be implemented similar to that discussed below in relation to FIG. 4, and/or may operate similar to that discussed below in relation to FIG. 5b. In some cases, multi-codeword parity based hard/soft input processing circuit 190 receives soft output information from hard data processing circuit 190 or from iterative data processing circuit 180 that can be used for calculating a soft data adjustment value. As more specifically discussed below in relation to claim 4, an LDPC decoder circuit may be shared between iterative data processing circuit 170, hard data processing circuit 180, and multi-codeword parity based hard/soft input processing circuit 190 to perform the decoding of the respective element.

Once all codewords that failed when processed by hard data processing circuit 180 have been re-processed by multi-codeword parity based hard/soft input processing circuit 190, memory access controller 120 transfers hard data 155 corresponding to the codewords that failed during processing by multi-codeword parity based hard/soft input processing circuit 190 to iterative data processing circuit 170. Iterative data processing circuit 170 includes a data decoder circuit that is guided by soft information generated by previous local iterations through the data decoder circuit. In addition, iterative data processing circuit 170 receives a soft data adjustment value 171 (soft data adjustment value 484 discussed in relation to FIG. 4 below) which is used to modify soft data processed by iterative data processing circuit 170.

Memory access controller 120 generates soft data corresponding to hard data 155 for the remaining failed codewords. The phrases “soft data”, “soft information”, or “soft decisions” are used in their broadest sense. In particular, “soft data”, “soft information”, or “soft decisions” indicate a likelihood that corresponding hard decisions are correct. Based upon the disclosure provided herein, one of ordinary skill in the art will recognize a variety of soft data that may be used in relation to different embodiments of the present invention. This soft data is generated by comparing the data accessed from flash memory cells 140 to different threshold values. The soft data is provided to iterative data processing circuit 170 as soft data 176. Using soft data 176, iterative data processing circuit 170 re-processes the remaining failed codewords. Each of the remaining failed codewords that is corrected using the iterative data processing circuit 170 is provided as a data output 175 to host controller circuit 160 and a syndrome for the converged codeword is provided as a syndrome output 176 to memory access controller circuit 120. Memory access controller circuit 120 accumulates the syndrome values of all converged codewords, and eliminates hard data 155 and soft data corresponding to the converged codewords from the buffer. In contrast, whenever a failed codeword is not rendered error free using the algorithm applied by iterative data processing circuit 170, an error indicator 179 is provided to host controller 160. Iterative data processing circuit 170 may be implemented similar to that discussed below in relation to FIG. 3, and/or may operate similar to that discussed below in relation to FIG. 5c.

Turning to FIG. 2a, a multi-codeword parity based encoding circuit 200 is shown in accordance with one or more embodiments of the present invention. In some cases, multi-codeword parity based encoding circuit 200 may be used in place of encoding circuit 164 of FIG. 1. Multi-codeword parity based encoding circuit 200 provides cross codewords encoding in accordance with some embodiments of the present inventions. Multi-codeword parity based encoding circuit 200 includes a controller data memory 210 that receives and stores user data to be transferred to flash memory cells. The stored data 212 is provided to a first level encoding circuit 220 that applies first level encoding to yield a first level encoded output 222. The encoding applied by first level encoding circuit 220 may include, for example, cyclic redundancy check encoding, scrambling and/or other known encoding processes.

First level encoded output 222 is provided to both a selector circuit 250 and a cross codewords encoding circuit 230. Cross codewords encoding circuit 230 applies an encoding algorithm to the codewords provided as first level encoded output 222 to yield a cross codewords error correction codeword 232. In some cases, the cross codewords encoding includes XORing all corresponding bit positions in the multiple codewords provided as first level encoded output 222 and an encoding bit is generated to yield a particular parity (e.g., odd or even parity) for the bit position including the corresponding position in cross codewords error correction codeword 232. The generated parity assumes the particular location in cross codewords error correction codeword 232, and the process is completed for each of the other bit positions in the multiple codewords provided as first level encoded output 222 to generate cross codewords error correction codeword 232. Cross codewords error correction codeword 232 is provided to selector circuit 250.

Selector circuit 250 selects one of cross codewords error correction codeword 232 or first level encoded output 222 to yield a channel encoder input codeword 252. Channel encoder input codeword 252 is provided to a channel ECC encoder 260 that applies an encoding algorithm to each of the codewords (i.e., each of the codewords provided as first level encoded output 222 and cross codewords error correction codeword 232) to yield an encoded output 275. Encoded output 275 is then prepared to be written to a storage medium. In some embodiments, the encoding algorithm applied by channel ECC encoder 260 is a low density parity check encoding algorithm as is known in the art. In such a case, encoded output 275 is a low density parity check encoded output.

It should be noted that in some embodiments the cross-codewords error correction codeword is not subjected to LDPC encoding. In such instances, it is possible to move a cross codewords encoding circuit 230 to after channel ECC encoder 260. In such case, the output of channel ECC encoder 260 is provided as an input to cross codewords encoding circuit 230. Cross codewords error encoding circuit 230 encodes the output from channel ECC encoder 260 by XORing corresponding elements across instances of encoded output 275 to yield a cross codewords error correction codeword that is provided along with encoded output 275 for storage to the flash memory device (not shown).

It should be noted that in some embodiments of the present invention that the output of channel ECC encoder corresponding to cross codewords error correction codeword 232 is provided to a scrambler circuit (not shown). Such a scrambler circuit scrambles the elements of encoded output 275 that correspond to the cross codewords error correction codeword 232 to yield a scrambled output. Scrambling may be done, for example, XORing a pseudo-random sequence with the data to make the data appear random. In such embodiments, the scrambled output is provided to an upstream processing circuit in place of encoded output 275. Such scrambling avoids a situation where all zeros are written to a storage medium.

Turning to FIG. 2b, an example output 280 generated by data encoding circuit of FIG. 2a is shown. Example output 280 includes a number of LDPC encoded codewords 214. Each of codewords 214 includes user data 216 and LDPC parity data 213. Each bit position (e.g., bit positions 234) of LDPC codewords are XORed to yield a selected parity for a corresponding bit position in a cross codewords error correction codeword 218. A first portion 219 of cross codewords error correction codeword 218 corresponds to the user data portions 216 of LDPC codewords 214. Even though LDPC parity data 213 are generated after cross codewords encoding, they are also possibly protected by cross codewords coding correction in some scenarios when the LDPC code is linear (all codewords are in the null space of the parity check matrix) and all codewords 214 and 218 are using the same LDPC parity check matrix. In these examples, the cross codewords encoding can be placed after channel ECC encoding circuit 260, and the cross codewords parity encoding covers bits in all user bits (data portions 216 and 219) and LDPC parity bits positions (data portions 213 and 223).

Turning to FIG. 2c, a block of data 290 is shown that includes a number of LDPC encoded codewords 214 (identified as A1-H1, A2-H2, A3-H3, A4-H4, A5-H5, A6-B6). Block of data 290 additionally includes a cross codewords error correction codeword 218 (identified as PARITY). When a flash memory is accessed, block of data 290 is read including the LDPC encoded codewords 214 and the cross codewords error correction codeword 218. The dashed lines in each of the LDPC encoded codewords 214 indicate encoding across the user data associated with that particular codeword. The dashed line extending from A1 to H1, from A2 to H2, from A3 to H3, from A4 to H4, from A5 to H5, and from A6 to B6 represents the cross codeword encoding applied by cross codewords encoding circuit 230. In some cases, the number of LDPC codewords that are associated with a single cross codewords error correction codeword varies as a function of the age of the flash memory device (i.e., the NAND memory cells). Such variance allows for increasing protection as a device ages (i.e.,

$$\frac{1}{\begin{matrix}number of codewords per cross \\ codewords error correction codeword\end{matrix}} )$$

by decreasing the number of codewords protected by a given cross codewords error correction codeword. Such an approach provides a systemaic way to decrease the code rate below the base LDPC code design code rate range.

Turning to FIG. 3, one implementation of an iterative data processing circuit is depicted that may be used in relation to embodiments of the present invention. In particular, iterative data processing circuit 300 may be used to replace iterative data processing circuit 170. Iterative data processing circuit 300 receives a data set 325 which corresponds to a combination of read data 107 and soft data 176 shown in FIG. 1. Read data 325 is stored to a memory circuit 350. Once a decoder circuit 370 is available, a previously stored data set 325 is accessed from memory circuit 350 as a decoder input 351. An adder circuit 353 adds a soft data adjustment value 301 to decoder input 351 to yield a modified decoder input 352. In some embodiments of the present invention, the decoder circuit 370 is a low density parity check decoder circuit as is known in the art. Based upon the disclosure provided herein, one of ordinary skill in the art will recognize a variety of decoder circuits that may be used in relation to various embodiments of the present invention.

Decoder circuit 370 applies a data decoding algorithm to modified decoder input 352 to yield a decoded output 371. Where decoded output 371 fails to converge (i.e., decoded output 371 includes errors), another iteration of the data decoding algorithm is applied to modified decoder input 352 guided by decoded output 371. This process is repeated until either decoded output 371 converges (i.e., is error free) or a maximum number of iterations are performed condition is met. Alternatively, where decoded output 371 converges, it is provided as a decoded output 372 to a hard decision buffer circuit 390. Hard decision buffer circuit 390 provides the hard decisions of decoded output 372 as a hard decision output 392. Hard decision output 392 corresponds to data output 175 of FIG. 1.

Turning to FIG. 4, a data processing circuit 400 applying a multi-codeword parity based processing is shown in accordance with some embodiments of the present inventions. Data processing circuit 400 includes a sample buffer circuit 475 that receives the hard data 420 derived from a flash memory device. The hard data is provided from sample buffer circuit 475 as sample output 477. Sample output 477 is provided to a data decoder circuit 450 that applies a data decoding algorithm to sample output 477 to yield a decoded output 452. For a first round of local iterations for each of the non-converged codewords, data decoder circuit 450 applies the data decoder algorithm guided by decoded output 452. Decoded output 452 is all zeros for the first local iteration applied to each of the non-converging codewords, and decoded output 452 is non-zero for subsequent local iterations of the same non-converged codeword. In some embodiments of the present invention, a default of ten local iterations is allowed for each global iteration. Data decoder circuit 450 may be, but is not limited to, a low density parity check decoder circuit as are known in the art. Based upon the disclosure provided herein, one of ordinary skill in the art will recognize a variety of data decoder circuits that may be used in relation to different embodiments of the present invention.

Where the original data is recovered (i.e., the data decoding algorithm converges) or a timeout condition occurs, data decoder circuit 450 provides the result of the data decoding algorithm as a data output 474. Data output 474 is provided to a hard decision output circuit 496 where the data is reordered before providing a series of ordered data sets as a data output 498. in addition, the accumulated cross codewords syndrome is updated to reflect the convergence.

Alternatively, where the data decoding algorithm fails to converge after a selected number of local iterations, a total decoded output 451 which is a total soft output for all non-converging codewords associated with a given cross codewords error correction codeword (including soft data for the cross codewords error correction codeword where it is non-converging) is provided to a cross codewords error correction circuit 480. Cross codewords error correction circuit 480 provides an interim soft data adjustment value 486 to a multiplier circuit 457 where it is multiplied by a scaling input 458 to yield a soft data adjustment value 484. Any scaling input 458 known in the art may be used in relation to different embodiments of the present invention. Soft data adjustment value 486 is updated by cross codewords error correction circuit 480 after all non-converged codewords associated with a given cross codewords error correction codeword are available from data decoder circuit 450 as total decoded output 451.

Soft data adjustment value 484 is provided to a cross codeword based modification circuit 460 (shown in dashed lines). Cross codeword based modification circuit 460 includes an adder circuit 453 that adds sample output 477 to soft data adjustment value 484 to yield modified decoder input 459. On the first round of local iterations for each of the non-converged codewords through data decoder circuit 450, data decoder circuit 450 processes sample output 477. During subsequent rounds of local iterations for each of the non-converged codewords through data decoder circuit 450, data decoder circuit 450 processes modified decoder input 459 instead of sample output 477.

Soft data adjustment value 486 is calculated based upon total decoded output 451 in accordance with the following equations:

LLR_{CCECC,in}=LLR_{Dec}(i.e., the total LLR generated by a hard input/soft input decoder);

sign{LLR_{CCECC,ext}}=AccumulatedCrossCodewordsSyndrome+xor(sign{LLR_{CCECC,in}[Other Failed Codewords]}); and

|LLR_{CCECC,ext}|=min(|LLR_{CCECC,in}[All Other Failed Codewords]|).

LLR is soft data also known in the art as log likelihood ratio data. LLR_{CCECC,in} is the prior soft data for the cross codewords error correction decoding, LLR_{CCECC,ext} is the extrinsic soft data for the cross codewords error correction decoding, xor(sign{LLR_{CCECC,in}[Other Failed Sectors]}) is the XOR of the signs of LLR_{CCECC,in} of all of the other failed codewords, and the AccumulatedCrossCodewordsSyndrome is the cross codeword error correction partial syndrome computed by XORing the bits in bit positions that are protected by the cross codewords error correction coding of converged user codewords and/or the converged cross codeword error correction codeword. Using data processing circuit 400 of FIG. 4 as an example, the interim cross codeword soft data adjustment value 486 are only valid for data portion that are protected by the cross codewords error correction coding.

Initial processing on sample output 477 is hard data input decoding that yields a soft data output. Later iterations may be soft data input decoding that yields a soft data output. In some embodiments of the present invention, the same LDPC decoding circuit may be shared between hard data processing circuit 180, multi-codeword parity based hard/soft input processing circuit 190, and iterative data processing circuit 170 discussed above in relation to FIG. 1. In such a case, the soft data from a prior iteration of, for example, hard data processing circuit 180 may be used as a soft data input for processing by multi-codeword parity based hard/soft input processing circuit 190. In such case, the available soft data is provided to cross codeword error correction circuit 480 where it can be used in place of total decoded output 451.

Turning to FIGS. 5a-5c, flow diagrams 500, 501, 502 show a method for processing data accessed from a flash memory in accordance with various embodiments of the present invention. Following flow diagram 500 of FIG. 5a, it is determined whether a read request has been received from a host controller requesting access to a flash memory (block 505). Where a read request is not received (block 505), it is determined whether a write request has been received (block 595). Where a write request is received (block 595), data received is formatted and written to a location in the flash memory indicated by an address received as part of the write request (block 597). This write process writes a data set including multi-tiered encoding similar to that discussed above in relation to FIGS. 2a-2c. Once the write completes, the process returns to block 505.

Alternatively, when a read access is received (block 505), it includes an address indicating a location from which the data is to be accessed. Data corresponding to the address (i.e., selected data) is then accessed from the flash memory at the location indicated by the read request (block 510). The selected data includes a block of data including a number of encoded codewords along with a cross codewords error correction codeword. A first codeword of the selected data is selected (block 515), and standard flash memory hard decoding is applied to the codeword (block 520). Such standard flash memory hard decoding may be any decoding processing known in the art that operates on hard data accessed from the slash memory. As such, various error correction may be applied to the hard data.

It is then determined whether the hard decoding resulted in an error free codeword (block 525). Where hard decoding resulted in an error free codeword (block 525), the error free codeword is provided as part of a read data output (block 530). In addition, the resulting syndrome is added to an accumulated cross codewords syndrome maintained for the block of data accessed from the flash memory (block 535). This accumulated cross codewords syndrome is a partial syndrome computed by XORing the bits in bit positions that are protected by the cross codewords error correction coding of converged user codewords and/or the converged cross codeword error correction codeword. At this juncture, the hard data for the currently processing codeword that was received from the flash memory is discarded. Alternatively, where hard decoding failed to yield an error free codeword (block 525), the hard data for the currently processing codeword that was received from the flash memory is stored to a buffer as a failed codeword (block 540).

It is determined whether another codeword from the block of data received from the flash memory remains to be processed (block 545). Where another codeword remains to be processed (block 545), the next codeword within the block of data received from the flash memory is selected for processing (block 550), and the processes of blocks 520-545 are repeated for the next codeword. This process is then repeated until all codewords within the block of data received from the flash memory. Once all of the codewords have been processed, the accumulated cross codewords syndrome represents a value of that can be used in relation for further processing of the remaining failed codewords. It is determined whether there are any failed codewords from all of the codewords of the block of data accessed from the flash memory (block 555). Where no failed codewords remain (block 555), processing of the block is complete. Otherwise, where failed codewords remain (block 555), multi-tiered decoding is applied to the remaining failed codewords (block 560). Such multi-tiered decoding is shown in dashed lines as detail of such is set forth in FIG. 5b.

Turning to FIG. 5b, flow diagram 502 shows one implementation of the process of block 560 of FIG. 5a is shown that may be used in relation to one or more embodiments of the present invention. Following flow diagram 502, one of the failed sectors is selected for processing (block 507). LDPC data decoding is applied to the selected failed codeword (block 512). Application of the LDPC data decoding to the hard data of the failed codewords derived from the flash memory corrects one or more errors and results in soft data (e.g., log-likelihood ratio data) that may be used to guide subsequent iterations of the data decoding algorithm processing the failed codeword.

It is determined whether the result of applying the LDPC decoding algorithm corrected all errors in the codeword (i.e., did the codeword converge) (block 517). Where the result of applying the LDPC decoding algorithm converged (block 517), the syndrome is that of the cross codewords error correction codeword updated to account for the newly converged codeword (i.e., the syndrome of the result is added to the syndrome of block 535 of FIG. 5a), the hard data and decoded outputs for the converged codeword are discarded, and the converged codeword is provided as a data output (block 522). In addition, the codeword that had previously failed, but now has converged is removed from the list of remaining failed codewords. Alternatively, where the result of applying the LDPC decoding algorithm failed to converge (block 517), hard data and decoded outputs for the failed codeword are buffered (block 527).

It is determined whether another failed codeword remains for initial processing (block 532). Where another failed codeword remains for initial processing (block 532), the next failed codeword is selected (block 537), and the processes of blocks 512-532 are repeated for the next failed codeword. This process is repeated until all failed codewords have been initially processed.

Alternatively, where no failed codewords remain for initial processing (block 532), one of the remaining failed codewords is selected for re-processing (block 542). The decoder inputs are updated based upon all other failed codeword data in the buffer and the accumulated syndrome from all converged codewords (block 547). This updating is done in accordance with the following equations:

LLR_{CCECC,in}=LLR_{Dec,ext};

sign{LLR_{CCECC,ext}}=AccumulatedCrossCodewordsSyndrome+xor(sign{LLR_{CCECC,in}[All Other Failed Codewords]}); and

|LLR_{CCECC,ext}|=min(|LLR_{CCECC,in}[All Other Failed Codewords]|).

LLR is soft data also known in the art as log likelihood ratio data. LLR_{CCECC,in} is the prior soft data for the cross codewords error correction decoding, LLR_{CCECC,ext} is the extrinsic soft data for the cross codewords error correction decoding, xor(sign{LLR_{CCECC,in}[All Other Failed Sectors]}) is the XOR of the signs of LLR_{CCECC,in} of all of the other failed codewords, and the AccumulatedCrossCodewordsSyndrome is the cross codeword error correction partial syndrome computed by XORing the bits in bit positions that are protected by the cross codewords error correction coding of converged user codewords and/or the converged cross codeword error correction codeword. Using data processing circuit 400 of FIG. 4 as an example, the cross codeword soft data adjustment value 482 and cross codeword soft data adjustment value 484 are only valid for data portion that are protected by the cross codewords error correction coding.

The LDPC decoding algorithm is re-applied to the selected failed codeword using the updated decoder inputs (block 552). This re-application of the data decoder algorithm to the failed sector is guided by the following updated decoder guide:

Updated Decoder Guide=(LLR_{CCECC,ext})×Scaling Factor.

In the preceding applications of the data decoder algorithm (i.e., during block 512), the decoder guide was:

Decoder Guide=(LLR_{Dec,ext})×Scaling Factor.

Thus, during application of the data decoder algorithm, soft data generated based upon the cross codewords error correction codeword is used to reprocess the failed data sectors.

It is determined whether the codeword converged (block 557). Where the codeword converged (block 557), the hard data and decoded outputs for the converged codeword are discarded, and the converged codeword is provided as a data output (block 567). In addition, the codeword that had previously failed, but now has converged is removed from the list of remaining failed codewords. Alternatively, where the result of re-applying the LDPC decoding algorithm failed to converge (block 557), hard data and decoded outputs for the failed codeword are buffered for further processing (block 562).

It is then determined whether additional failed codewords remain to be processed (i.e., whether any failed codewords have not yet been processed on this iteration) (block 572). Where additional failed codewords remain to be processed (block 572), the next failed codeword is selected (block 577) and the processes of blocks 547-572 are repeated for the next failed codeword. Alternatively, where it is determined that no additional failed codewords remain to be processed (block 572), it is determined whether another iteration through all of the remaining failed codewords is desired (block 582). In some case, up to ten iterations through the failed codewords is allowed. Where another iteration is allowed (block 582), the processes of blocks 542-582 are repeated for the remaining failed codewords. Otherwise, where no additional iterations are allowed (block 582), the process completes and a return to block 565 of FIG. 5a occurs.

Returning to FIG. 5a and following flow diagram 500, it is determined where any failed codewords remain after the multi-tiered decoding has completed (block 565). Where no failed codewords remain (block 565), processing of the block is complete. Otherwise, where failed codewords remain (block 565), soft data generated decoding is applied to the failed codewords (block 570). Such soft data generated decoding is shown in dashed lines as detail of such is set forth in FIG. 5c. It should be noted that in blocks 526-541 of FIG. 5c that multiple iterations of soft data decoding may be performed using the soft data generated by the decoding process in block 570.

Turning to FIG. 5c, a flow diagram 501 shows one implementation of the process of block 570 of FIG. 5a is shown that may be used in relation to one or more embodiments of the present invention. Following flow diagram 501, a first of the failed codewords is selected (block 504), and soft information corresponding to the remaining failed codewords is either accessed or generated (block 506). Such soft information indicates a probability that given elements of the accessed data are correct. In some cases, this soft information is provided by a solid state memory device from which the data was accessed. In other cases, the soft information is generated. Such generation of soft information may be done using any approach known in the art for generating soft data. As one example, generation of soft information may be done similar to that disclosed in U.S. patent application Ser. No. 14/047,423 entitled “Systems and Methods for Enhanced Data Recovery in a Solid State Memory System”, and filed by Xia et al. on Oct. 7, 2013. The entirety of the aforementioned application was previously incorporated herein by reference for all purposes. It should be noted that the soft information may be generated for an entire block of data read from a flash memory device, and only the soft data corresponding to the remaining failed codewords is kept.

The hard data for the failed codewords that is maintained in the buffer in block 562 of FIG. 5b and the corresponding soft information is stored as a data set to a memory (block 511). It is then determined whether the data decoder circuit is available for processing (block 516). Where the data decoder circuit is available for processing (block 516), a previously stored data set is accessed from the memory as a decoder input (block 521). A data decoding algorithm is applied to the accessed data set to yield a decoded output (block 526). Where available (i.e., for the second and later iterations), a previous decoded output is used to guide application of the data decoding algorithm. In some embodiments of the present invention, the data decoding algorithm is a low density parity check decoding algorithm as are known in the art. Based upon the disclosure provided herein, one of ordinary skill in the art will recognize a variety of data decoding algorithms that may be used in relation to different embodiments of the present invention. It is determined whether the decoded output converged (block 531). Where it is determined that the decoded output converged (block 531), the decoded output is provided as read data (block 536).

Alternatively, where it is determined that the decoded output failed to converge (block 531). It is determined whether another iteration of the data decoding algorithm is allowed (block 541). In some cases, a maximum number of iterations of the data decoding algorithm is fixed or programmable. This is effectively a timeout condition. In some cases, the maximum number of allowable iterations of the data decoding algorithm is one hundred. Based upon the disclosure provided herein, one of ordinary skill in the art will recognize other numbers of iterations that may be allowed in relation to different embodiments of the present invention. Where another local iteration is not allowed (block 541), an error is indicated (block 546). Otherwise, where another iteration of the decoding algorithm is allowed (block 541), the processes of blocks 526-541 are repeated.

It is determined whether another failed codeword remains to be processed (block 551). Where another failed codeword remains to be processed (block 551), the next failed codeword is selected (block 556), and the processes of blocks 506-551 are repeated for the next failed codeword. Where no failed codewords remain to be processed (block 551), the process completes and a return to FIG. 5a occurs.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A system for accessing a flash memory device, the system comprising:
a flash memory read circuit including:
a hard data processing circuit operable to apply a hard data decoding algorithm to a set of hard data derived from flash memory cells, wherein application of the hard data decoding results in converged codewords and at least one non-converged codeword;
an accumulated syndrome circuit operable to compute a partial syndrome of the converged codewords; and
a multi-codeword parity based processing circuit including:
a cross codeword error correction circuit operable to calculate a soft data adjustment value based at least in part upon the at least one non-converged codeword; and
a data decoding circuit operable to apply a secondary data decoding algorithm to the at least one non-converged codeword guided by a decoder input generated in part from the soft data adjustment value.

2. The system of claim 1, wherein the partial syndrome is computed by XORing the bits in bit positions that are protected by the cross codewords error correction codeword of the converged codewords.

3. The system of claim 1, wherein the secondary data decoding algorithm is a low density parity check decoding algorithm.

4. The system of claim 1, wherein the at least one non-converged codeword includes at least a first non-converged codeword and a second non-converged codeword, and wherein applying the secondary data decoding algorithm yields a first converged codeword corresponding to the first non-converged codeword, and a third non-converged codeword corresponding to the second non-converged codeword.

5. The system of claim 1, wherein the flash memory read circuit further includes:
an iterative data processing circuit operable to:
receive soft data corresponding to the third non-converged codeword, wherein the soft data is generated using multiple instances of the hard data of the third non-converged codeword each corresponding to different threshold values; and
apply a tertiary data decoding algorithm to the third non-converged codeword guided by the soft data.

6. The system of claim 5, wherein the tertiary data decoding algorithm is a low density parity check decoding algorithm.

7. The system of claim 1, wherein the system is implemented as part of a solid state storage device.

8. The system of claim 7, wherein the solid state storage device includes a flash memory device having the flash memory cells.

9. The system of claim 1, wherein the system is implemented as part of an integrated circuit.

10. A method for accessing a flash memory device, the method comprising:
providing a flash memory device, wherein the flash memory device includes a data block including at least: a first codeword, a second codeword, a third codeword, and a cross codewords error correction codeword;
accessing the data block from the flash memory device;
applying a hard data decoding algorithm to the data block, wherein application of the hard data decoding results in a converged codeword corresponding to the first codeword, a first non-converged codeword corresponding to the second codeword, a second non-converged codeword corresponding to the third codeword, and a decoded output corresponding to the cross codewords error correction codeword;
computing a partial syndrome of at least the converged codeword;
using a multi-codeword parity based processing circuit to calculate a soft data adjustment value based at least in part upon the decoded output corresponding to at least the first non-converged codeword and the second non-converged codeword, and applying a secondary data decoding algorithm to the first non-converged codeword and the second non-converged codeword guided by a decoder input generated in part from the soft data adjustment value.

11. The method of claim 10, wherein computing the partial syndrome of at least the converged codeword includes XORing the bits in bit positions that are protected by the cross codewords error correction codeword of the at least the converged codeword.

12. The method of claim 10, wherein the secondary data decoding algorithm is a low density parity check decoding algorithm.

13. The method of claim 10, wherein the converged codeword is a first converged codeword, wherein applying the secondary data decoding algorithm yields a second converged codeword corresponding to the first non-converged codeword, and a third non-converged codeword corresponding to the second non-converged codeword.

14. The method of claim 13, the method further comprising:
receiving soft data corresponding to the third non-converged codeword, wherein the soft data is generated using multiple instances of the hard data of the third non-converged codeword each corresponding to different threshold values; and
applying a tertiary data decoding algorithm to the third non-converged codeword guided by the soft data.

15. The method of claim 14, wherein the tertiary data decoding algorithm is a low density parity check decoding algorithm.

16. A solid state storage device, the solid state storage device comprising:
a flash memory device, wherein the flash memory device includes at least: a first codeword, a second codeword, a third codeword, and a cross codewords error correction codeword;
a flash memory read circuit including:
a hard data processing circuit operable to apply a hard data decoding algorithm to the data block, wherein application of the hard data decoding results in a converged codeword corresponding to the first codeword, a first non-converged codeword corresponding to the second codeword, a second non-converged codeword corresponding to the third codeword, and a decoded output corresponding to the cross codewords error correction codeword;
an accumulated syndrome circuit operable to compute a partial syndrome of at least the converged codeword; and
a multi-codeword parity based processing circuit including:
a cross codeword error correction circuit operable to calculate a soft data adjustment value based at least in part upon a decoded data set corresponding to the first non-converged codeword and a decoded data set corresponding to the second non-converged codeword; and
a data decoding circuit operable to apply a secondary data decoding algorithm to the first non-converged codeword and the second non-converged codeword guided by a decoder input generated in part from the soft data adjustment value.

17. The solid state storage device of claim 16, wherein the secondary data decoding algorithm is a low density parity check decoding algorithm.

18. The solid state storage device of claim 16, wherein the converged codeword is a first converged codeword, wherein applying the secondary data decoding algorithm yields a second converged codeword corresponding to the first non-converged codeword, and a third non-converged codeword corresponding to the second non-converged codeword; and wherein the solid state storage device further comprises:
an iterative data processing circuit operable to:
receive soft data corresponding the third non-converged codeword, wherein the soft data is generated using multiple instances of the hard data of the third non-converged codeword each corresponding to different threshold values; and
apply a tertiary data decoding algorithm to the third non-converged codeword guided by the soft data.

19. The solid state storage device of claim 18, wherein the tertiary data decoding algorithm is a low density parity check decoding algorithm.

20. The solid state storage device of claim 16, wherein computing the partial syndrome of at least the converged codeword includes XORing the bits in bit positions that are protected by the cross codewords error correction codeword of the at least the converged codeword.

21. The solid state storage device of claim 16, wherein a number of codewords for each cross codewords error correction codeword varies as a function of the quality of a subset of flash cells within the flash memory device.

22. The solid state storage device of claim 21, wherein when the quality decreases, the number of codewords for each cross codewords error correction codeword decreases.

23. The solid state storage device of claim 16, wherein a number of codewords for each cross codewords error correction codeword varies as a function of a number of erase cycles applied to the flash memory device.

24. A solid state storage device, the solid state storage device comprising:
a flash memory device, wherein the flash memory device includes at least: a first codeword, a second codeword, and a cross codewords error correction codeword;
a flash memory read circuit including:
a multi-codeword parity based processing circuit including:
a cross codeword error correction circuit operable to calculate a soft data adjustment value based at least in part upon the decoded output corresponding to a non-converged codeword; and
a data decoding circuit operable to apply a data decoding algorithm to a first non-converged codeword corresponding to the first codeword and a second non-converged codeword corresponding to the second codeword guided by a decoder input generated in part from the soft data adjustment value.

25. The device of claim 24, wherein a first iteration of the data decoding algorithm operates on hard data only, and wherein a second iteration of the data decoding algorithm uses soft data.
